(19) United States
(12) Patent Application Publication
(10) Pub. No.: US 2012/0085403 A1
(43) Pub. Date: Apr. 12, 2012

(54) METHOD FOR PRODUCING A CONTACT, A CONTACT AND SOLAR CELL COMPRISING A CONTACT

(75) Inventors: Erik Sauar, Oslo (NO); Andreas Bentzen, Oslo (NO); Karl Ivar Lundahl, Oslo (NO)

(73) Assignee: RENEWABLE ENERGY CORPORATION ASA, Sandvika (NO)

(21) Appl. No.: 13/146,741

(22) PCT Filed: Jan. 27, 2010
(86) PCT No.: PCT/NO2010/000031

§ 371 Date: Dec. 16, 2011

Related U.S. Application Data
(60) Provisional application No. 61/148,415, filed on Jan. 30, 2009.

(30) Foreign Application Priority Data
Jan. 30, 2009 (GB) 0901604.9

(51) Int. Cl. H01L 31/0224; H01L 31/18

(52) U.S. Cl. 136/256; 438/72; 257/E31.127

(57) ABSTRACT

Method for providing at least one contact on a back surface of a solar cell comprising a silicon substrate comprising depositing a passivating layer onto the silicon substrate and thereafter providing at least one contact site and further providing a patterned exposed silicon surface. Then depositing a metal layer and annealing the structure to form metal silicide. Thereafter the process involves optionally removing excess metal and finally applying metal onto the silicide to form at least one contact. A solar cell comprising a back surface, the back surface comprising a contact, produced by the above mentioned method. A contact for back surface of a solar cell comprising a silicon substrate, an amorphous silicon layer deposited onto the silicon substrate, a reflective layer with at least one opening deposited onto the amorphous silicon layer, in the at least one opening there resides silicide, with additional metal covering the silicide.

### FIELD OF THE INVENTION

The present invention relates to a method of producing a contact for a back surface of a silicon solar cell. The present invention also relates to a contact produced by this method and a solar cell comprising the contact.

### BACKGROUND

Cutting the cost per energy unit produced is a prime objective of the solar cell industry. There are three ways of reaching this objective. One is to reduce the cost of production, the other is increase the efficiency of the product and the third is to do both actions simultaneously.

One way to increase efficiency of the solar cell is to enable it to capture more light. In a standard multi-crystalline silicon solar cell, the entire back of the solar cell is typically covered with metal, usually aluminum. One drawback of this configuration is the relatively poor passivating properties of the aluminum at the aluminum/silicon interface, which leads to excessive charge carrier recombination and thus lower current collection efficiencies.

Creating localized back contacts can avoid the abovementioned drawback of implementing a complete metalized back surface of a solar cell. It allows the areas in between the contacts to be covered with passivating layers and thus increases the current collecting efficiency.

Additionally, localized back contacts also allow for the fabrication of back contacted solar cells, which avoid the shading from the front side metal contacts. Back side contacting requires separation of the p-Si contact and the n-Si contact.

For all purposes mentioned above, the creation of localized contacts require patterning, and most known back-contact cells designs are expensive to manufacture because of the necessity to apply and remove expensive masks or use expensive metal separation techniques.

The present invention seeks to tackle the abovementioned challenges by providing a structured silicon surface where all non-silicon surfaces may become contact separation areas while the silicon surfaces will become the basis of the metal conductors.

### PRIOR ART

Patent application WO 2008/039078 A2 describes a cost efficient method of a back contact silicon solar cell. In the method, an aluminum back contact is applied on the whole back surface and later the contacts are separated by appropriate method. Patent application WO2006/110048 A1 describes a method for employing a passivation layer structure consisting of amorphous silicon of silicon carbon bottom layer and an amorphous silicon nitride top layer.

### SUMMARY OF THE INVENTION

According to the invention there is provided a method for producing a contact for a silicon solar cell, where the method comprises applying either a silicon substrate with doped regions of alternating p-type and n-type conductivity or a silicon substrate with p-type or n-type conductivity. The method comprises the following steps:
a) depositing a passivating layer onto the silicon substrate
b) providing at least one contact site
c) providing a patterned exposed silicon surface
d) non-selectively depositing a metal layer
e) annealing the structure to form metal silicide
f) optionally removing excess metal after step e)
g) applying metal onto the silicide to form at least one contact

According to the invention there is provided a contact for a back surface of a solar cell comprising a silicon substrate onto which a passivating layer is applied and partly removed in areas where a contact shall be formed. Furthermore, the contact comprises silicide regions onto or into the silicon substrate.

### OBJECTIVE OF THE INVENTION

The main objective of the invention is to provide a cost efficient method for processing the back surface of a solar cell in such a way that at least one contact is created.

The objective of the invention may be achieved by the features as set forth in the description below and in the appended claims and attached figures.

### DESCRIPTION OF THE INVENTION

The present invention relates to a method of producing a back contact on the back surface of a silicon solar cell by use of low temperature silicide formation and possible contact separation done by a wet chemical etching step.

The method of the invention may employ a back contact on the back side of a solar cell that also has a front side contact or it can employ a solar cell that is produced in such a way that it has all the contact sites on the back side.

The invention may employ any silicon wafer or thin film acting as the absorber material. The absorber material will hereby be referred to as “substrate”. The substrates include wafers or thin layers or films of mono-, micro-, and multi-crystalline silicon and any known and conceivable configuration of the p and n doped regions. This includes, but is not limited to, configurations
where the contact to n-type Si is situated on the front side and is contacted by another method while the contact to the p-type Si is situated on the back side of the solar cell and is to be produced by the method described in this invention, or
where the contact to p-type Si is situated on the front side and is contacted by another method while the contact to the n-type Si is situated on the back side of the solar cell and is to be produced by the method described in this invention, or
where both the contact to n-type Si and the contact to p-type Si are situated on the back of the solar cell and are to be produced by the method described in this invention.

The term “front surface” denotes the surface of the solar cell that is exposed to direct sunlight. The term “back surface” is the opposite side to the front surface. The term “back contact” means an electrical contact to the solar cell that is situated on the back surface of the solar cell.

The term “back-contacted solar cell” means that all contact sites reside on the back surface of the solar cell.

The term “p-doped region” means a surface area of the substrate where a doping material resulting in an increased number of positive charge carriers is added into the silicon material within a certain distance below the surface forming a region of the substrate with a surface layer with p-type conductivity. The term “n-doped region” means a surface area of the substrate where a doping material resulting in increased number of negative charge carriers (mobile electrons) is added into the silicon material within a certain distance below the surface forming a region of the substrate with a surface layer with n-type conductivity.

The term “front contacted solar cell” means a solar cell with contacts on the front surface and the back surface.

The said doped regions can be made by any of the following processes or combination of the following processes:
in-diffusion of dopant material from the surface of the substrate into the substrate within a certain distance below the substrate surface,
deposition of appropriately doped amorphous silicon, microcrystalline silicon, nanocrystalline silicon or crystalline silicon. By “appropriately doped” it is meant that the dopant concentration can vary with thickness and have values from 0 cm⁻³ to 1×10²¹ cm⁻³.
Implantation of dopant material by means bombardment by accelerated dopant species, followed by a heat treatment of appropriate temperatures in order to electrically activate the dopant species in the silicon material.

The term “silicon material” denotes any silicon containing material that will form metal silicide with the deposited metal layer upon the appropriate thermal treatment. This comprises crystalline silicon, amorphous silicon, micro-crystalline silicon and nano-crystalline silicon. The silicon material may include 0-40 atomic percent hydrogen.

The term “contact site” hereby means an area on the surface of the substrate where the solar cell is to be contacted. This said area can reside on an n-doped region, a p-doped region, n-type silicon material or p-type silicon material.

The term “providing a contact site” denotes processing the structure in such a way that between the contact site and the metal layer to be deposited, there only resides silicon material on top of the contact site. The important point is that regardless of the prior steps, there should only reside silicon material at the contact site.

The term “silicide” denotes a compound that has silicon together with more electropositive elements. These elements can typically be, for example nickel, palladium, titanium, silver, gold, aluminium, copper, tungsten, vanadium, chromium.

The term “exposed silicon surface” denotes silicon material that is exposed to the ambient.

The term “structure” denotes the device at any process step.

Substrates for back-contacted solar cells should have at least one region of each type conductivity p and n on its back side, but typically there will be several doped regions with alternating conductivity in an interdigitated pattern.

This invention provides a method for producing at least one back contact for a solar cell, regardless of front surface treatment prior to application of the method described in this document. The invention further relates to a back contact and a solar cell including the back contact.

The figures are made in such a way that the front surface of the solar cell faces the bottom of the page and the back surface faces the top of the page. The drawings are schematic and are not to scale. In the figures the drawings show the contact sites as they would typically be in a back-contacted solar cell. The attached figures show embodiments of the invention.

### SHORT DESCRIPTION OF THE FIGURES

The invention will be described in detail below, with reference to the enclosed drawings which show embodiments of the invention where:

FIGS. 1a-f show schematically a cross section of a first embodiment of the method of the invention

FIGS. 2a-d show schematically a cross section of a second embodiment of the method of the invention

FIGS. 3a-e show schematically a cross section of a third embodiment of the method of the invention

FIGS. 4a-g show schematically a cross section of a fourth embodiment of the method of the invention

FIGS. 5a-e show schematically a cross section of a fifth embodiment of the method of the invention

### DETAILED DESCRIPTION OF THE INVENTION

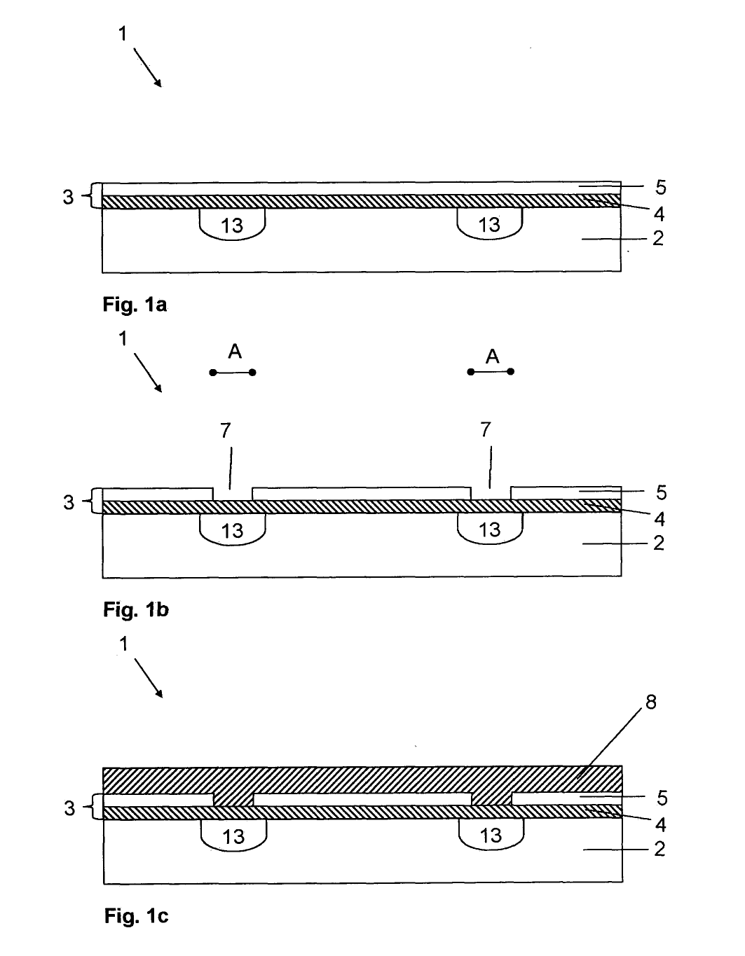

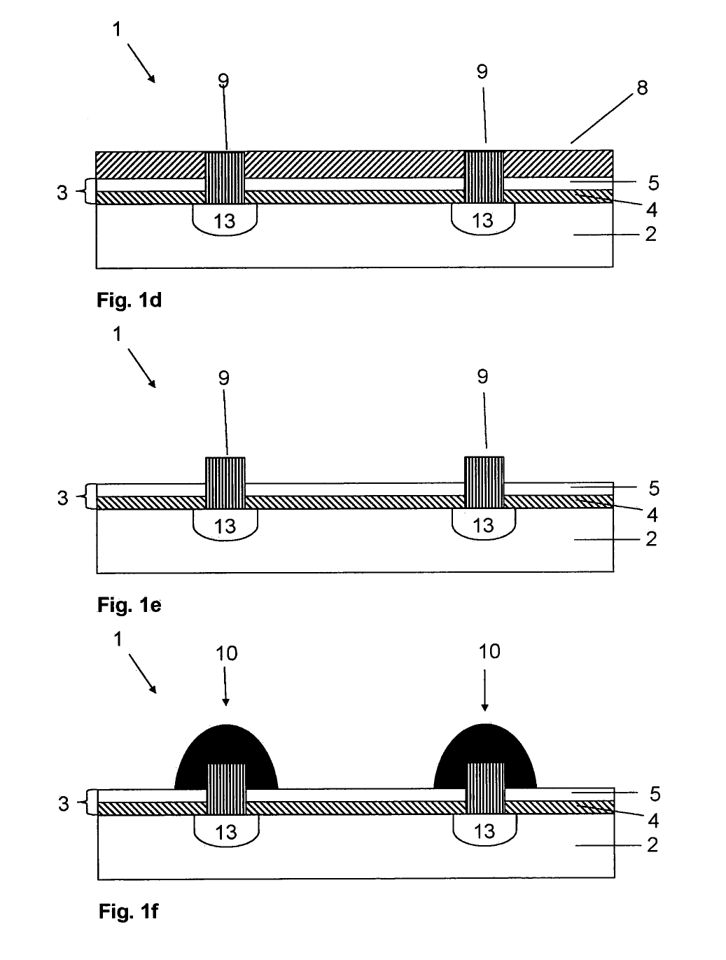

In more detail the invention relates to a method for producing at least one contact for a back surface of a silicon solar cell. The method comprises applying a silicon substrate 2 with doped regions and then depositing a passivating layer 3 onto the silicon substrate 2 as shown in FIG. 1a. In this document a passivating layer 3 means a single passivating layer or a passivating stack of layers.

The back contact structure 1 produced by the method in this invention comprises a passivating layer 3 deposited on a silicon substrate 2. The passivating layer 3 preferably comprises a hydrogenated amorphous silicon (a-Si:H) layer 4 and a hydrogenated amorphous silicon nitride (a-SiNₓ:H) layer 5.

After deposition of the passivating layer 3, contact sites are provided by processing the structure in such a way that there only resides silicon material between the contact site and the metal to be deposited. Typically this comprises removing any non-silicon material, for example a-SiNₓ:H, located in the area(s) defines as contact sites(s). Typically, this step leads to a pattern of openings 7 where the contacts shall be formed.

The at least one opening 7 is located where the at least one contact shall be created. After forming the at least one opening 7 a metal layer 8 is deposited onto the structure 1 by a non-selective method.

A non-selective metal deposition method can comprise sputtering or evaporation and means that the metal deposits on all exposed surfaces. It is also possible to perform plating in a non-selective way.

After deposition of the metal layer 8 the structure 1 is subjected to an annealing treatment (temperature treatment). Silicide can be made at temperatures typically ranging from 175° C. to 550° C., more preferably 225° C. to 500° C., most preferably 275° C. to 450° C. for 5 to 60 seconds, depending on the metal used. This thermal treatment can comprise a temperature profile that varies linearly or non-linearly with time. The temperature treatment step can be done by e.g. rapid thermal annealing.

The metal layer 8 in the openings 7 reacts with the silicon material creating a silicide region 9. The non-silicide metal is removed by a selective etch as explained for embodiment 1 of the invention. The silicide regions 9 are electroplated or electroless plated to reduce the electrical resistance of the contacts. The plated metal can for example be copper.

The invention also provides a solar cell comprising a back contact structure produced by the method according to the invention.

The role of the passivating layer 3 is to enhance the current collecting properties of the silicon structure by enhanced surface passivation. For some applications it is desirable to increase the back surface reflection while the passivating layers 3 do not solely serve as an optimal back reflector of light that has passed through the silicon substrate 2. In this case, a reflective layer 6 is placed on top of the passivating layer 3 and serves to increase the back reflectance of photons back into the silicon structure thus increasing the current generating properties of the silicon structure 1, as exemplified in embodiments 2, 3, 4 and 5.

The figures show the method for making two contacts. However, it should be emphasized that the method comprises the production of one or more contacts.

In a first embodiment of the invention a passivating layer 3, comprising an amorphous silicon bottom layer and a silicon nitride top layer, is first deposited on the silicon substrate 2.

Subsequently contact sites are provided by removing the silicon nitride layer 5 in area A, creating at least one opening 7 in the silicon nitride layer 5 in areas above the at least one specifically doped region 13. In this process some or all of the underlying amorphous silicon layer 4 may also be removed in the at least one opening 7, as seen in FIG. 1b. In this way a contact site has been provided. In addition a patterned exposed silicon surface has also simultaneously been provided. The said removal of the amorphous silicon layer 4 in the at least one opening 7 may be done in the same step as the said removal of the silicon nitride layer 5 in the at least one opening 7, or in a separate step. Subsequently a metal layer 8 is deposited onto the passivating layer 3 at least filling the at least one opening 7, as seen in FIG. 1c. By filling it is meant that all or most of the exposed silicon in the opening 7 is covered by metal 8. Then the silicon structure 1 is subjected to the appropriate annealing treatment (temperature treatment) such that a metal silicide 9 is formed in the areas where the metal 8 is in contact with silicon material, as seen in FIG. 1d. Subsequently the contacts are separated by exposing the metal to a selective etch which removes the metal 8 which has not formed silicide 9, as seen in FIG. 1e.

The passivating layer 3 can typically comprise a hydrogenated amorphous silicon (a-Si:H) layer or a hydrogenated amorphous silicon nitride (a-SiNₓ:H) layer. In other embodiments the passivating layer 3 can comprise an a-Si:H layer 4 and an a-SiNₓ:H layer 5. In further embodiments the passivating layer 3 comprises of (from the silicon substrate and up): an a-Si:H layer, an a-SiNₓ:H layer and an a-Si:H layer. The invention is not limited to these materials.

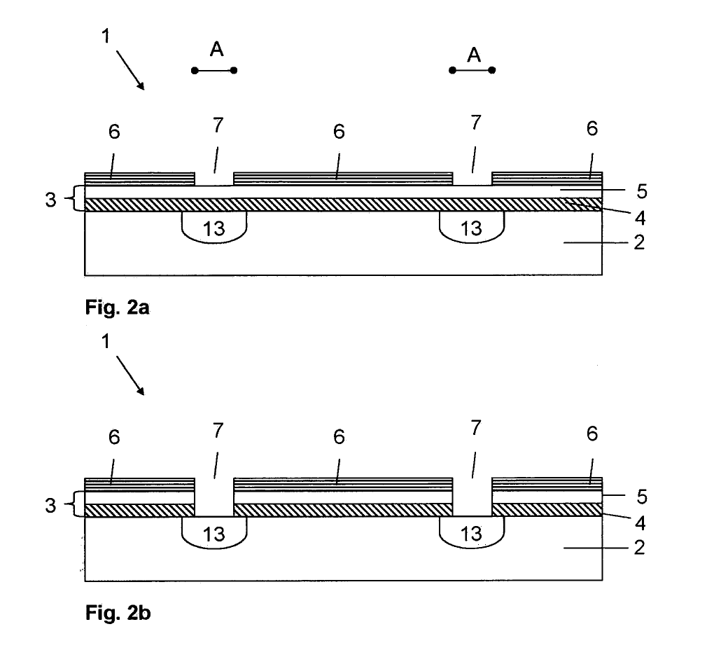

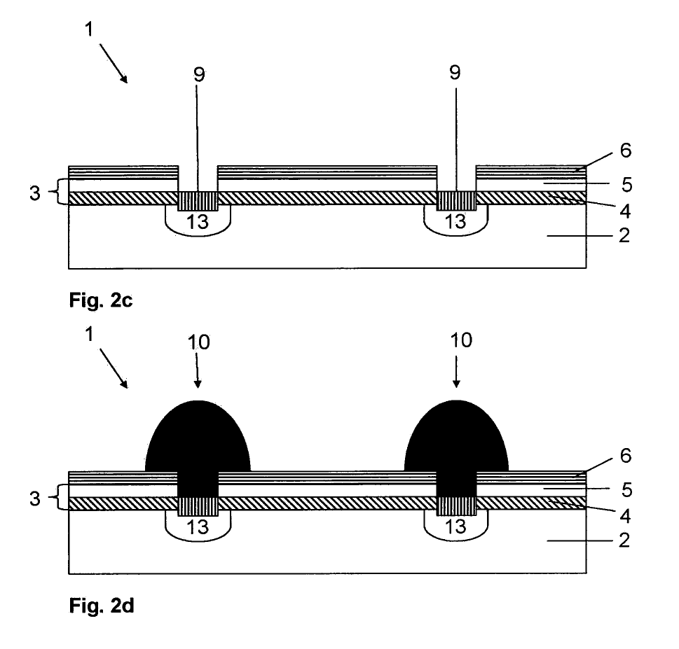

In a second embodiment of the method for producing a back contact, a patterned reflective layer 6 is deposited onto the passivating layer 3 with at least one opening 7 defining where the contact shall be formed, as seen in FIG. 2a. All or most of, the passivating layer 3 exposed in the openings 7 is removed as shown in FIG. 2b, and explained in more detail below. The entire silicon nitride layer 5 and the entire amorphous silicon layer 4 exposed to the ambient in the at least one opening 7 in area A have to be removed. In this way a contact site has been created. In addition a patterned exposed silicon surface has also simultaneously been provided. The next step involves non-selective deposition of a metallic layer 8. Then the structure 1 is annealed to form silicide regions 9 on or below the surface of the silicon structure 2 where the at least one opening 7 is located. Subsequently the contacts are separated by exposing the metal to a selective etch which removes the metal which has not formed silicide 9. This is shown in FIG. 2c. Typically one can apply a highly conductive metal to the silicide regions 9 to thicken the contacts 10 in order to reduce electrical resistance. This is illustrated in FIG. 2d.

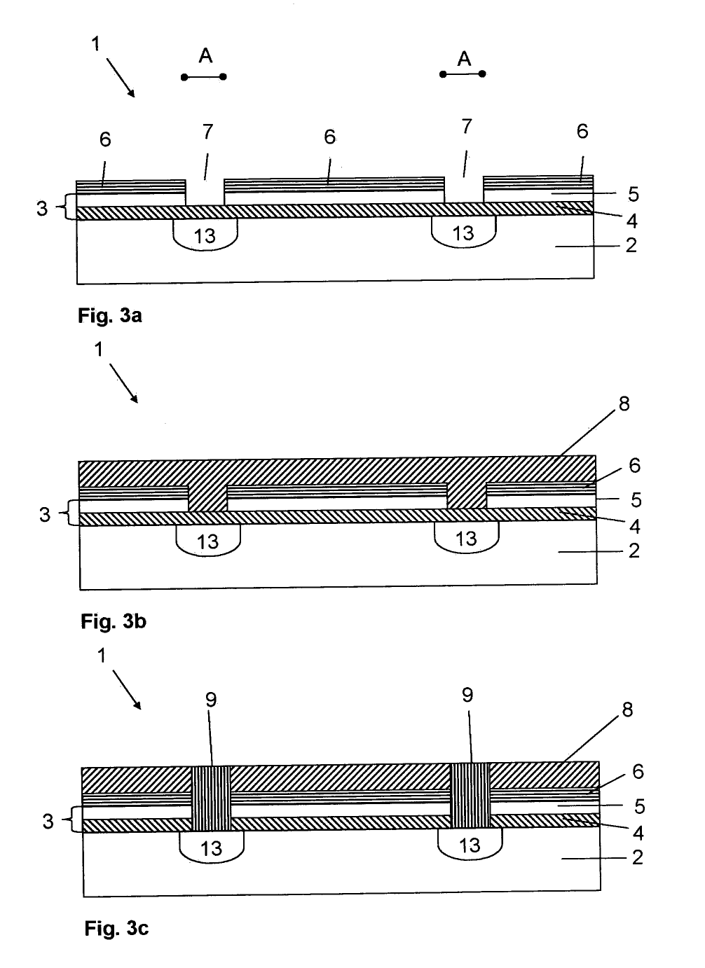

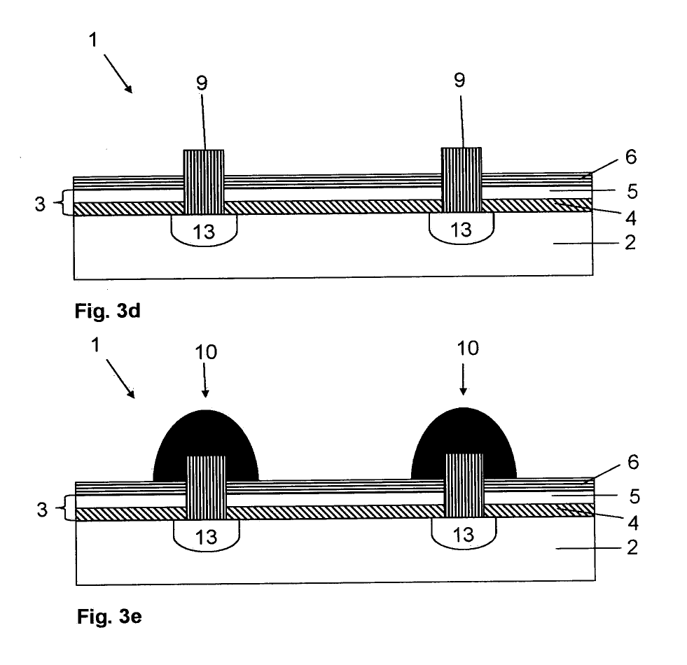

FIG. 3a shows schematically a third embodiment of the method for producing at least one back contact where the a-SiNₓ:H layer 5 is removed according to the pattern defined by the reflective layer 6. FIG. 3b shows the silicon structure with a metal layer applied in such a way that it covers the reflective layer 6 and fills the openings 7 according to the patterns defined by the reflective layer 6. FIG. 3c shows schematically the same silicon structure after an annealing step which has led to formation of silicide 9. FIG. 3d shows the silicon structure after the removal of metal 8 which has not formed silicide. FIG. 3e shows schematically the next step where metal has been applied to form contacts in connection with the silicide regions.

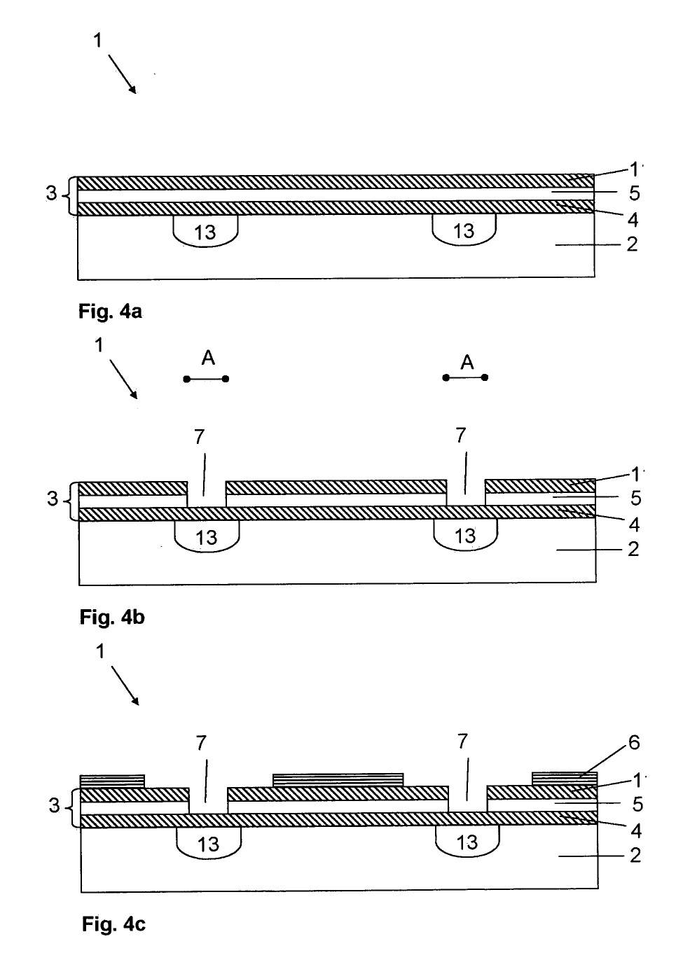

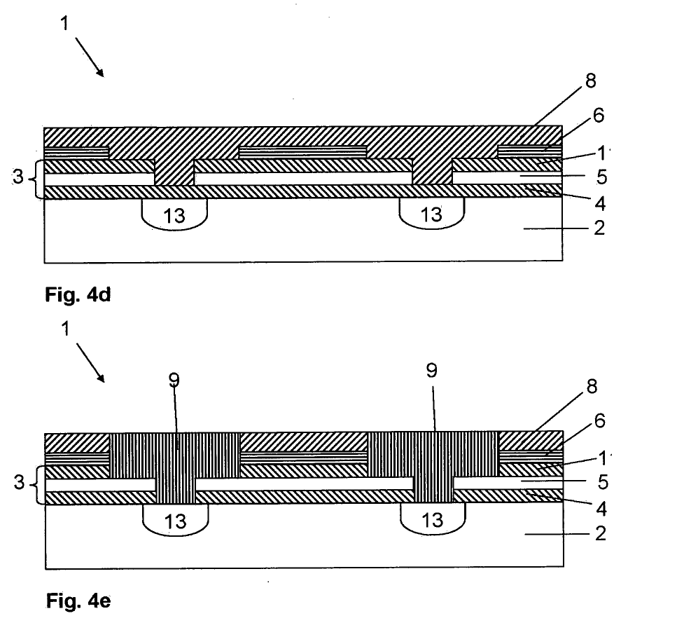

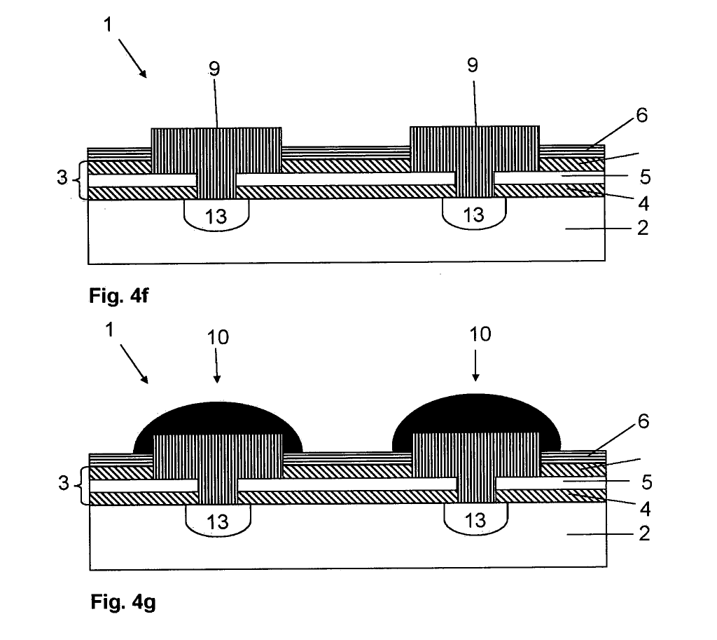

FIG. 4a shows schematically a fourth embodiment of the method for producing at least one back contact where the passivating layer 3 comprises an a-Si:H layer 4, onto which there is deposited an a-SiNₓ:H layer 5, onto which there is deposited an a-Si:H layer 11. FIG. 4b shows the same silicon structure 1 after at least some of the passivating layer 3 has been removed in an opening 7 to such an extent that the a-Si:H layer 11 and the a-SiNₓ:H layer 4 has been removed and that at least some of the a-Si:H layer 3 remains in the opening 7, as explained below In this way a contact site has been provided. This step can typically be done by laser ablation or ink jet etching. FIG. 4c shows the same structure where a reflective layer has been applied onto the a-Si:H layer 11 covering least in some of the area where the opening 7 has not been made. In this way a patterned exposed silicon surface has been provided. FIG. 4d shows the structure 1 after a metal layer has been deposited at least filling the opening 7. FIG. 4e shows the same structure 1 after an annealing step has led to silicide formation 9 in the regions where the metal layer 8 was in contact with a-Si:H. FIG. 4f shows the same structure 1 after metal 8 that had not formed silicide 9 has been removed, typically by a selective etch. Then a metal is applied to the silicide 9 to form contacts 10.

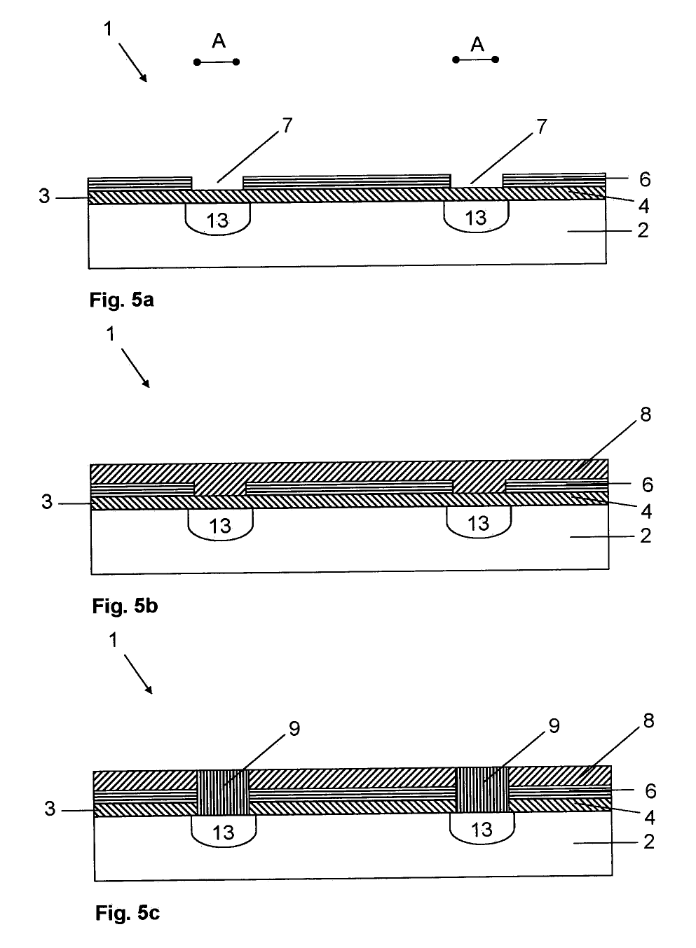

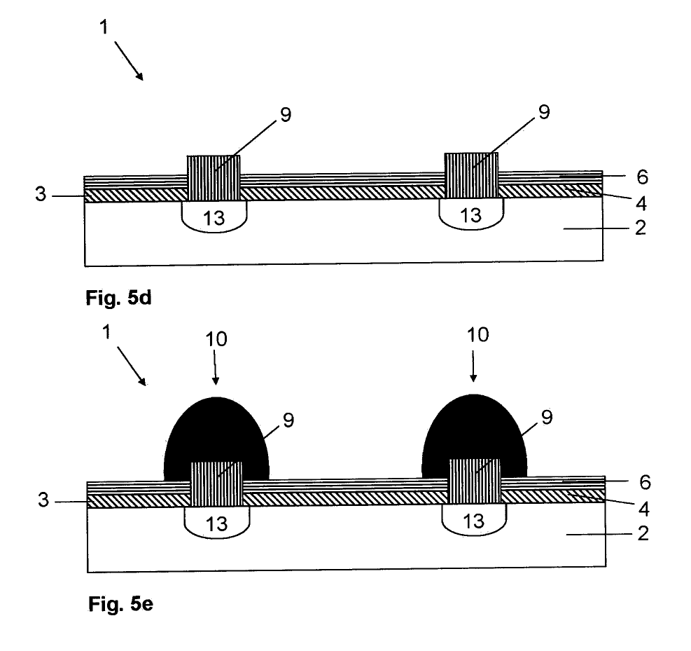

FIG. 5a shows schematically a fifth embodiment of the method for producing at least one back contact where the passivating layer 3 comprises an a-Si:H layer 3. Onto the passivating layer 3 is deposited a patterned reflective layer 6 with at least one opening 7 where the at least one contact shall be formed, thus providing a patterned exposed silicon surface. Onto the structure 1 a metal layer 8 is deposited (FIG. 5b) with a subsequent temperature treatment resulting in the metal layer 8 reacting with the exposed silicon surface to form at least one silicide region 9 (FIG. 5c). Subsequently the non-reacted metal 8 is removed by a selective etch leaving the silicide region intact, as seen in FIG. 5d. Lastly a metal 10 is deposited on the at least one silicide region 9.

### EMBODIMENTS OF THE INVENTION

These embodiments refer to treatment of the back side of a solar cell only and assume that the front side is fully treated. The method of the invention is not restricted in any way to this assumption and will also cover situations where the front side is either treated after the back side treatment described in this invention or that the front side treatment steps are done simultaneously or in between the steps described in this invention.

The embodiments refer to making more than one contact, but the method of the invention refers to making at least one contact.

### First Embodiment

The first embodiment of the method of the invention has as a starting point a silicon substrate 2 which typically has a back surface with doped regions 13 and has received full front side treatment. The doped regions 13 can be of the same type of conductivity or with alternating p-type and n-type conductivity. The doped regions 13 can have the same or different doping concentration as the substrate. The silicon structure 1 can be produced either from a monocrystalline silicon wafer, a multicrystalline silicon wafer or a silicon based thin film. The back surface might be planar or textured, e.g. by wet chemistry or plasma treatment.

The back surface is first cleaned for example by exposure to a mixture of H₂S0₄ and H₂0₂, a mixture of HCl, H₂0₂ and H₂0, or a mixture of NH₄0H, H₂0₂ and H₂0, followed by an oxide removal, e.g. in diluted HF.

The passivating layer/layers 3 are applied on the back surface of the silicon substrate 2. The passivating layer 3 comprises a hydrogenated amorphous silicon (a-Si:H) layer 4 and a hydrogenated amorphous silicon nitride (a-SiNₓ:H) layer 5, as described in patent WO2006/110048 A1. The passivating layers can be applied using plasma enhanced chemical vapor deposition (PECVD) or other deposition techniques suitable for this purpose such as hot wire CVD (HWCVD), expanding thermal plasma (ETP), electron cyclotron resonance (ECR), sputtering or similar techniques. The structure to this point is illustrated in FIG. 1a.

The role of the passivating layer 3 is to enhance the charge carrier transportation properties at the surface and bulk of the silicon substrate 2 and hence increase its current collecting capabilities. The thickness of the a-Si:H layer 4 is typically 5-200 nm, preferably 10-60 nm. The thickness of the a-SiNₓ:H is 10-150 nm, preferably 20-100 nm.

In the next step at least one opening 7 is created in the passivation layer 3 in such a way that it is aligned with the doped region 13 and thereby constitutes the area where the contact shall subsequently be formed. This is illustrated in FIG. 1b. By “opening” it is meant the at least the a-SiNₓ:H layer 5 is removed while the a-Si:H layer 4 is either removed or at least partly intact. FIG. 1b illustrates the method where at least parts of the a-Si:H layer 4 is left intact.

This procedure constitutes providing a contact site in the areas comprising said openings 7.

The at least one opening 7 in the passivation layer 3 can be created by, but not limited to, the following techniques:
ink jet etching
laser ablation
applying a patterned etch resistant mask, etching (by wet chemistry or plasma etching) the passivation layer 3 and subsequently removing the mask
screen print etching

After the at least one opening 7 has been formed a metal layer 8 is deposited non-selectively in such a way that metal at least fills the at least one opening 7, as illustrated in FIG. 1c. The metal layer 8 can be applied by for example, but not limited to, evaporation or sputtering.

Suitable metals for evaporation and subsequent silicide formation include nickel, palladium, titanium, silver, gold, aluminium, copper, tungsten, vanadium, chromium, or any combination of these metals

A relevant metal for back side silicide formation is nickel. During silicide formation, the monosilicide (NiSi) is preferable as this alloy has the lowest electrical resistance of the nickel silicides. Added to his, the process must be optimised for the minimum contact resistance between the silicon and the silicide.

After the metal layer 8 has been applied, the structure 1 is subjected to the appropriate annealing step in order to facilitate the formation of silicide 9 where the metal layer 8 is in contact with silicon material (FIG. 1d). The metal in the at least one opening 7 reacts with the silicon material creating at least one silicide region 9. Silicide can be made at temperatures typically ranging from 175° C. to 550° C., more preferably 225° C. to 500° C., most preferably 275° C. to 450° C. for 5 to 60 seconds, depending on the metal used. This thermal treatment can comprise a temperature profile that varies linearly or non-linearly with time. The temperature treatment step can be done by e.g. rapid thermal annealing.

It can be beneficial to anneal the passivating layers 4 and 5 prior to the application of the metal layer 8 due to the possible mismatch between the temperatures and times needed for the passivation layer 3 optimization and the silicide 9 formation anneal steps.

If the method of the invention is implemented on the back side of a front contacted solar cell, the contact separation may not be necessary.

If the method of the invention, however, is applied to the back side of a back-contacted cell, one would typically have more than one contact and thus these contacts need to be separated, as illustrated in FIG. 1e. A relevant method to remove the metal 8 which has not reacted to form silicide 9 is by selective etching, employing an etching solution which etches the silicide 9 much slower than the metal 8. This can be done by exposure to, for example, HNO₃ or a mixture of HNO₃ and HCl.

Alternatively, the contacts can be separated by laser ablation, screen print etching or inkjet etching.

Subsequently, the contacts are thickened by electroplating or electroless plating resulting in larger contacts 10 with lower electrical resistance.

### Second Embodiment

The second embodiment of the method of the invention has as a starting point a silicon substrate 2 which typically has a back surface with doped regions with alternating p-type and n-type conductivity and has received full front side treatment. The silicon structure can be produced either from a monocrystalline silicon wafer, a multicrystalline silicon wafer or a silicon based thin film. The back surface might be planar or textured, e.g. by wet chemistry or plasma treatment.

The back surface is first cleaned for example by exposure to a mixture of H₂S0₄ and H₂0₂, a mixture of HCl, H₂0₂ and H₂0, or a mixture of NH₄0H, H₂0₂ and H₂0, followed by an oxide removal, e.g. in diluted HF.

The passivating layer/layers 3 are applied on the back surface of the silicon substrate 2. The passivating layer 3 comprises a hydrogenated amorphous silicon (a-Si:H) layer 4 and a hydrogenated amorphous silicon nitride a-SiNₓ:H layer 5, as described in patent WO2006/110048 A1. The passivating layers can be applied using plasma enhanced chemical vapor deposition (PECVD) or other deposition techniques suitable for this purpose such as hot wire CVD (HWCVD), expanding thermal plasma (ETP), electron cyclotron resonance (ECR), sputtering or similar techniques.

The role of the passivating layer 3 is to enhance the charge carrier transportation properties at the surface and bulk of the silicon substrate 2 and hence increase its current collecting capabilities. The thickness of the a-Si:H layer 4 is typically 5-200 nm, preferably 10-60 nm. The thickness of the a-SiNₓ:H is 10-150 nm, preferably 20-100 nm. The thicknesses of the layers can be individually adjusted to optimize for back reflection while maintaining the passivation properties.

On top of the passivating layer 3 is applied a patterned reflective layer 6, typically by ink-jetting leaving at least one opening 7 in the reflective layer 6 which is aligned with the at least one contact site 13. This can be seen in FIG. 2a. Alternatively, the reflective layer 6 can be applied covering most of, or all of the passivating layer 3, with subsequent removal of some of the reflective layer 6 to define at least one openings 7. Both these methods are equivalent and is covered by the phrase ‘applying a reflective resin layer 6 with at least one opening 7’.

The reflective layer 6 material can comprise a resin that in turn comprises reflection enhancing additives. The purpose of the reflective layer in this embodiment is:
to define the pattern of openings 7 of the passivation layer,
to serve as a protective mask for the passivating layers under the subsequent etching step,
to ensure enhanced back reflection of photons that have not been absorbed in the silicon substrate 2.

The openings 7 in the reflective layer 6 define the pattern for which the passivating layer 3 will be opened towards the silicon substrate 2. The passivating layer 3 is etched in an appropriate solution which removes, all or most of the passivating layer 3, i.e. the a-SiNₓ:H layer 5 and the a-S:H layer 4, as seen in FIG. 2b.

The appropriate solution can be, but not limited to, a solution of diluted, concentrated or buffered HF, or solution of diluted or concentrated KOH, or solution of diluted or concentrated NaOH, or a mixture comprising HF, HN0₃, and CH₃COOH, or a combination thereof. The choice of method for obtaining the openings is not important. An important feature is that the passivation layer 3 must be locally removed to expose the underlying silicon material. In this way a contact site is provided.

After opening the passivating layer 3 in a pattern defined by the reflective layer 6, a metal layer 8 is applied by appropriate method on top of the reflective layer 6 filling the openings 7 in the passivating layer 3 to an extent that the metal layer 8 is in contact with the silicon substrate 2.

This method can constitute metal evaporation, sputtering or electroless plating, which will result in a full coverage on the back side of the silicon structure 2, i.e. a non-selective deposition of the metal layer 8. Suitable metals for evaporation and subsequent silicide formation include nickel, palladium, titanium, silver, gold, aluminium, copper, tungsten, vanadium, chromium, or any combination of these metals

A relevant metal for back side silicide formation is nickel. During silicide formation, the monosilicide (NiSi) is preferable as this alloy has the lowest electrical resistance of the nickel silicides. Added to his, the process must be optimised for the minimum contact resistance between the silicon and the silicide. Silicide can be made at temperatures typically ranging from 175° C. to 550° C., more preferably 225° C. to 500° C., most preferably 275° C. to 450° C. for 5 to 60 seconds, depending on the metal used. This thermal treatment can comprise a temperature profile that varies linearly or non-linearly with time. The temperature treatment step can be done by e.g. rapid thermal annealing.

After the metal layer 8 has been applied, the structure 1 is subjected to the appropriate annealing step in order to facilitate the formation of silicide 9 where the metal layer 8 is in contact with the exposed silicon surface in the at least one opening 7. Silicide can be made at temperatures typically ranging from 175° C. to 550° C., more preferably 225° C. to 500° C., most preferably 275° C. to 450° C. for 5 to 60 seconds, depending on the metal used. This thermal treatment can comprise a temperature profile that varies linearly or non-linearly with time. The temperature treatment step can be done by e.g. rapid thermal annealing.

It can be beneficial to anneal the passivating layers 4 and 5 prior to the application of the reflective layer due to the possible mismatch between the temperatures and times needed for the passivation layer 3 optimization and the silicide 9 formation anneal steps.

The metal which has not formed silicide can be removed by a selective etch, as described in embodiment 1 and seen in FIG. 2c.

Subsequently, the contacts will be thickened by electroplating or electroless plating (FIG. 2d) resulting in larger contacts 10 with lower electrical resistance.

### Third Embodiment

A third embodiment of the method according to the invention is shown in FIGS. 3a to 3e.

The first steps are identical to the first steps in the second embodiment. The method starts with a silicon substrate 2 which typically has a back side with doped regions with alternating p-type and n-type conductivity and has received full front side treatment. The silicon structure can be produced either from a monocrystalline silicon wafer, a multicrystalline silicon wafers or a silicon based thin film. The back surface might be planar or textured, either by wet chemistry or plasma treatment. The backside is typically cleaned in the same way as in the first embodiment.

Onto the silicon substrate 2, the passivating stack of layers 3 is applied. The passivating stack of layer 3 comprises a hydrogenated amorphous silicon (a-Si:H) layer 4, and on top of this a hydrogenated amorphous silicon nitride layer (a-SiNₓ:H) 5. Layers 4,5 are deposited in the same way as in the first embodiment.

The role of the passivating layers 4,5 is to enhance the charge carrier transportation properties at the surface and bulk of the silicon substrate 2 and hence increase its current collecting capabilities. The thickness of the a-Si:H layer 4 is typically 5-200 nm, preferably 10-60 nm. The thickness of the a-SiN_{c}:H is 10-150 nm, preferably 20-100 nm. The thicknesses of the layers are individually adjusted to optimize for back reflection while maintaining the passivation properties

In the next step there is applied a patterned reflective layer 6 onto layer 5, in the same way as in the first embodiment. The reflective layer 6 is typically deposited by ink-jetting leaving at least one opening 7 in the reflective layer 6 which is aligned with the contact site 13. Alternatively, the reflective layer 6 can be applied covering most of, or all of the passivating layer 5, with subsequent removal of some of the reflective layer 6 to define a pattern with openings 7. These methods are equivalent and are covered by the phrase “applying a reflective resin layer 6 with at least one opening 7 defined by a pattern”.

The reflective layer material can comprise a resin that in turn comprises reflection enhancing additives. The purpose of applying the reflective resin is:
to define the pattern of openings 7 of the passivation layer,
to serve as a protective mask for the passivating layers under the subsequent etching step, and
to ensure enhanced back reflection of photons that have not been absorbed in the silicon substrate 2.

The openings 7 in the reflective layer 6 define the pattern for which the passivating layer 5 will be exposed.

FIG. 3a shows the next step where the part of the a-SiNₓ:H layer 5 not being covered by the reflective layer 6, has been removed, leaving the a-Si:H layer 4 at least partially intact. This is typically done by exposure to diluted HF solution.

FIG. 3b shows the next step where metal layer 8 has been applied non-selectively on top of the reflective layer 6 and the deposited metal is in contact with the a-Si:H layer 4 through the openings 7 defined by the reflective resin layer 6.

The application of the metal is performed in the same way as for the first embodiment. Suitable metals are also identical to the suitable metals in the first embodiment.

After the metal layer 8 has been applied, the structure 1 is subjected to the appropriate annealing step in order to facilitate the formation of silicide 9 where the metal layer 8 is in contact with the exposed silicon surface in the at least one opening 7 (FIG. 3c). Silicide can be made at temperatures typically ranging from 175° C. to 550° C., more preferably 225° C. to 500° C., most preferably 275° C. to 450° C. for 5 to 60 seconds, depending on the metal used. This thermal treatment can comprise a temperature profile that varies linearly or non-linearly with time. The temperature treatment step can be done by e.g. rapid thermal annealing.

The silicide formation in this embodiment can typically be done at a lower temperature than for the second embodiment due to the higher temperature required for silicide formation in crystalline silicon. This results in a silicide formation that stops predominantly at the a-Si:H/silicon substrate 2 interface. This is shown in FIG. 3c.

It can be beneficial to anneal the passivating layers 4 and 5 prior to the application of the reflective resin layer due to the possible mismatch between the temperatures and times needed for the passivation layer 3 optimization and the silicide 9 formation anneal steps.

If the method of the invention is implemented on the back side of a front side contacted solar cell where contact separation may not be necessary, there may be no further process steps.

If the method of the invention, however, is applied to the back side of a back side contacted cell, one would typically have more than one contact and thus these contacts need to be separated, as illustrated in FIG. 3e. A relevant method is to remove the metal 8 which has not reacted to form silicide 9 by selective etching where only the residual metal 8 is removed. This can be done by exposure to, for example, HNO₃ or a mixture of HNO₃ and HCl.

Alternatively, the contacts can be separated by laser ablation, screen print etching or inkjet etching.

Subsequently, the contacts are thickened by electroplating or electroless plating (FIG. 30 resulting in larger contacts 10 with lower electrical resistance.

### Fourth Embodiment

A fourth embodiment of the method according to the invention is shown in FIGS. 4a to 4f.

The method starts with a substrate 2 with a passivating layer 3 deposited onto it. In this embodiment of the invention the passivating layer 3 comprises a bottom amorphous silicon layer 4, onto which an amorphous silicon nitride layer 4 is deposited, onto which an amorphous silicon layer 11 is deposited. This passivating stack is shown in FIG. 4a.

The passivating layers can be applied by techniques mentioned in the first embodiment of the invention.

Then, at least the top amorphous silicon layer 11 and the amorphous silicon nitride layer 5 are removed leaving openings 7 where at least some of the amorphous silicon layer 4 is intact. This removal step is shown in FIG. 4b and illustrates that the at least one opening 7 is aligned with the at least one contact site 13. See FIG. 4b.

The removal step can comprise utilizing ink jet etching, screen print etching, laser ablation, applying a photolithographic mask with subsequent etching and mask removal or other appropriate technique.

On top of the remaining passivating layer 3 is applied a reflective layer 6 in areas where subsequent silicide formation is not wanted. This is illustrated in FIG. 4c.

The order at which the two last steps are done is not important. It is also possible to cover all of the passivating layer 3 completely with a reflective layer 6, and in the next step, the reflective layer, the top a-Si:H layer and the a-SiN:H layer is removed for creation of the opening 7. Removal of the above mentioned material layers can be done by e.g. laser ablation.

The next step is shown in FIG. 4d where a metal layer 8 is applied non-selectively, filling at least the areas that are not covered with reflective resin layer 6. The metal layer can be applied by evaporation, sputtering or other appropriate technique.

Suitable metals for evaporation and subsequent silicide formation include nickel, palladium, titanium, silver, gold, aluminium, copper, tungsten, vanadium, chromium, or any combination of these metals

The invention is not restricted to these choices of metals, it may apply using any material that forms a highly conductive silicide or silicon alloy on both p- and n-type silicon.

After the metal layer 8 has been applied, the structure 1 is subjected to the appropriate annealing step in order to facilitate the formation of silicide 9 where the metal layer 8 is in contact with the exposed silicon surface in the at least one opening 7 (FIG. 4e). Silicide can be made at temperatures typically ranging from 175° C. to 550° C., more preferably 225° C. to 500° C., most preferably 275° C. to 450° C. for 5 to 60 seconds, depending on the metal used. This thermal treatment can comprise a temperature profile that varies linearly or non-linearly with time. The temperature treatment step can be done by e.g. rapid thermal annealing. This process forms silicide 9 in the regions where the metal is in contact with amorphous silicon in layer 4 or layer 11.

Hence, the metal atop of the reflective layer 6 does not form silicide.

In the case where the contacts that are formed need to be separated, such as in a back contacted solar cell, the metal which has not formed silicide can be removed by a selective etch, as mentioned in embodiment 1.

For application as a back contact on a two side contacted solar cell where the cell is also contacted on the front side of the cell, the metal which has not formed silicide may not need to be removed.

Subsequently, the contacts are thickened by electroplating or electroless plating resulting in larger contacts 10 with lower electrical resistance.

### Fifth Embodiment

A fifth embodiment of the invention is illustrated in FIGS. 5a-5e.

The method starts with a substrate 2 with a passivating layer 3 deposited onto it. In this embodiment of the invention the passivating layer 3 comprises an amorphous silicon (a-Si:H) layer 4.

On top of the passivating layer 3 is applied a patterned reflective layer 6, typically by ink-jetting leaving at least one opening 7 in the reflective layer 6 which is aligned with the at least one contact site 13. This can be seen in FIG. 5a. Alternatively, the reflective layer 6 can be applied covering most of, or all of the passivating layer 3, with subsequent removal of some of the reflective layer 6 to define at least one openings 7. Both these methods are equivalent and is covered by the phrase ‘applying a reflective resin layer 6 with at least one opening 7’.

After this step a metal layer is applied non-selectively onto the whole structure 1 by means of evaporation or sputtering, as seen in FIG. 5b.

Suitable metals for evaporation and subsequent silicide formation include nickel, palladium, titanium, silver, gold, aluminium, copper, tungsten, vanadium, chromium, or any combination of these metals

After the metal layer 8 has been applied, the structure 1 is subjected to the appropriate annealing step in order to facilitate the formation of silicide 9 where the metal layer 8 is in contact with the exposed silicon surface in the at least one opening 7 (FIG. 5c). Silicide can be made at temperatures typically ranging from 175° C. to 550° C., more preferably 225° C. to 500° C., most preferably 275° C. to 450° C. for 5 to 60 seconds, depending on the metal used. This thermal treatment can comprise a temperature profile that varies linearly or non-linearly with time. The temperature treatment step can be done by e.g. rapid thermal annealing. This process forms silicide 9 in the regions where the metal is in contact with amorphous silicon in layer 4, as seen in FIG. 5c.

Hence, the metal atop of the reflective layer 6 does not form silicide.

In the case where the contacts that are formed need to be separated, such as in a back contacted solar cell, the metal which has not formed silicide can be removed by a selective etch, as mentioned in embodiment 1 and seen in FIG. 5d.

For application as a back contact on a two side contacted solar cell where the cell is also contacted on the front side of the cell, the metal which has not formed silicide need not be removed.

Subsequently, the contacts are thickened by electroplating or electroless plating resulting in larger contacts 10 with lower electrical resistance, as seen in FIG. 5e.

1.-30. (canceled)

31. Method for providing a structure with at least one contact on a back surface of a solar cell comprising a silicon substrate, at least one doped region, where the method comprises the following steps:
a) depositing a passivating layer comprising an a-Si:H layer onto the back surface of the silicon substrate,
b) providing at least one contact site,
c) providing a patterned exposed silicon surface,
d) non-selectively depositing a metal layer,
e) annealing the structure to form metal silicide, and
f) applying metal onto the silicide to form at least one contact.

32. Method according to claim 31,
wherein
step b) and c) can be done simultaneously.

33. Method according to claim 31,
wherein
step c) can be performed before step b).

34. Method according to claim 31,
wherein step b) further comprises
depositing a reflective layer with at least one opening and subsequently providing the contact site in the at least one opening.

35. Method according to claim 31,
wherein step c) further comprises depositing a reflective layer onto the passivating layer.

36. Method according to claim 31,
wherein step e) is followed by removing excess metal.

37. Method according to claim 31,
wherein step a) comprises
depositing an a-SiNₓ:H layer on top of the a-Si:H layer.

38. Method according to claim 31,
wherein step a) comprises
depositing an a-SiNₓ:H layer on top of the a-Si:H layer and then depositing an a-Si:H layer on top of the a-SiNₓ:H layer.

39. Method according to claim 34,
wherein the reflective layer is a reflective resin layer.

40. Method according to claim 34,
wherein the reflective layer is a reflection enhanced polymer or a reflection enhanced epoxy.

41. Method according to claim 34,
wherein the reflective layer is deposited by inkjet or spraying.

42. Method according to claim 31,
wherein the metal in the metal layer in step d) is nickel.

43. Method according to claim 31,
wherein the application of metal in step d) is performed by evaporation or sputtering.

44. Method according to claim 31,
wherein the application of metal in step f) is performed by electro plating or eletroless plating.

45. A contact for a back surface of a solar cell comprising a silicon substrate, an amorphous silicon layer deposited onto the silicon substrate, a reflective layer with at least one opening deposited onto the amorphous silicon layer, in the at least one opening there resides silicide, with additional metal covering the silicide.

46. A solar cell comprising a back surface, the back surface comprising a contact, wherein at the contact is provided on the back surface of the solar cell by a method according to claim 31.

47. A solar cell comprising a back surface, the back surface comprising a contact according to claim 45.

48. Method according to claim 32,
wherein step e) is followed by removing excess metal.

49. Method according to claim 33,
wherein step e) is followed by removing excess metal.

50. Method according to claim 34,
wherein step e) is followed by removing excess metal.
